(19) United States
(12) Patent Application Publication
(10) Pub. No.: US 2010/0117690 A1
(43) Pub. Date: May 13, 2010

(54) SEMICONDUCTOR DEVICE

(75) Inventor: Yoshiyasu DOI, Kawasaki (JP)

Correspondence Address: ARENT FOX LLP, 1050 CONNECTICUT AVENUE, N.W., SUITE 400, WASHINGTON, DC, 20036, US

(73) Assignee: FUJITSU LIMITED, Kanagawa (JP)

(21) Appl. No.: 12/692,185

(22) Filed: Jan. 22, 2010

Related U.S. Application Data
(63) Continuation of application No. PCT/JP2007/064523, filed on Jul. 24, 2007.

(51) Int. Cl. H03K 3/00

(52) U.S. Cl. 327/108

(57) ABSTRACT

A semiconductor device includes a first buffer circuit transmitting input signals, a second buffer circuit having a lower drive capability than the first buffer circuit and transmitting the input signals, and a control circuit detecting transitions of the input signals, and activating the first buffer circuit during a period when the input signals make the transitions.

### CROSS-REFERENCE TO RELATED APPLICATIONS

This application is a Continuation of International Application No. PCT/JP2007/064523, with an international filing date of Jul. 24, 2007, which designating the United States of America, the entire contents of which are incorporated herein by reference.

### FIELD

The present embodiment relates to a semiconductor device.

### BACKGROUND

A semiconductor device is speeding up and highly integrated resulting from miniaturization of a semiconductor processing technology. On the other hand, heat quantity generated by an increase of power consumption becomes large. There are problems in the increase of the heat quantity in the semiconductor device such that not only performance degradation and short operating life of the semiconductor device are incurred but also cost increases caused by a countermeasure against heat releasing of equipments and so on in which the semiconductor device is used, battery driving time is shortened and so on.

A power consumption P_{IC} of the semiconductor device is generally given by “P_{IC}∝(f×V_{dd}²×Cₚ)”. Here, “f” is an operating frequency, “V_{dd}” is a power supply voltage, and “Cₚ” is a parasitic capacitance. Methods controlling the operating frequency and the power supply voltage in accordance with an operating status of the semiconductor device and reducing the parasitic capacitance are used as the method to attain the low power consumption of the semiconductor device.

A shift of a buffer circuit used to transfer a clock and data, from a CMOS type to a CML (Current Mode Logic) type capable of performing a higher-speed operation has been studied resulting from a request of improving the operation speed of the semiconductor device.

FIG. 14 is a view illustrating a configuration example of a CML type differential buffer circuit. In FIG. 14, reference symbols IP and IN are input terminals, and they are respectively coupled to gates of N-channel type transistors M101, M102. Differential signals relating to the clock and data are inputted to the input terminals IP, IN.

Sources of the N-channel type transistors M101, M102 are coupled to a current source IS101 of which one end is coupled relative to a reference potential Vss. Drains of the N-channel type transistors M101, M102 are coupled to a power supply line to which a power source potential Vdd is supplied, via resistances R101, R102 as loads.

A coupling point between the drain of the N-channel type transistor M102 and the resistance R102 is coupled to an output terminal OP. Similarly, a coupling point between the drain of the N-channel type transistor M101 and the resistance R101 is coupled to an output terminal ON.

High-speed operation is possible in the CML type differential buffer circuit as illustrated in FIG. 14 compared to the CMOS type buffer circuit. However, a constant current is always required in the CML type differential buffer circuit to maintain an amplitude when the clock and data are transmitted, and a current relating to a state transition and a current relating to the amplitude maintenance are commonly used. Accordingly, the CML type differential buffer circuit consumes current regardless of an operating frequency.

For example, a signal outputted from the output terminal OP changes from low level to high level as a signal inputted from the input terminal IP changes from low level to high level during a state transition time (a period ST1 illustrated in FIG. 15). It is necessary to reduce resistance values Rload of the resistances R101, R102 as the loads to enable the high-speed operation. Here, a current “I” consumed at the differential buffer circuit is determined by a voltage amplitude required for an output, and a current value corresponding to the Rload is necessary. Namely, a large current is necessary if the resistance values Rload of the resistances R101, R102 as the loads are small.

On the other hand, the current “I” and the Rload are also the similar in the CML type differential buffer circuit during a period of amplitude maintenance (a period ST2 illustrated in FIG. 15), and the current is steadily consumed.

Namely, a power consumption Pₐₘₚ of the CML type differential buffer circuit is given by “Pₐₘₚ∝(V_{dd}×I)” when a power supply voltage of the differential buffer circuit is “V_{dd}” and the operating current is “I”. The power consumption Pₐₘₚ does not depend on the operating frequency of the differential buffer circuit. Accordingly, the CML type differential buffer circuit consumes the similar electric power as at a high frequency operation time even at a low frequency operation time when the high-speed operation is not required.

A semiconductor circuit in which currents at a stand-by time and at an operating time are switched by controlling a current source of a common emitter type bipolar differential amplifier circuit, and an operating current thereof is changed in accordance with a circuit operation is proposed in the following patent document 1.

Patent Document 1: Japanese Laid-open Patent Publication No. 1-261918

### SUMMARY

According to an aspect of the embodiment, a semiconductor device includes a first buffer circuit transmitting input signals, a second buffer circuit having a lower drive capability than the first buffer circuit and transmitting the input signals, and a control circuit detecting transitions of the input signals, and activating the first buffer circuit during a period when the input signals make the transitions.

The object and advantages of the embodiment will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a view illustrating a configuration example of a semiconductor device according to a first embodiment;

FIG. 2 is a view illustrating an example of an output waveform of the semiconductor device illustrated in FIG. 1;

FIG. 3 is a view illustrating a concrete configuration example of the semiconductor device in the present embodiment;

FIG. 4 is a view illustrating an example of an output waveform of a high-pass filter illustrated in FIG. 3;

FIG. 5 is a view representing a relationship between an operating frequency and a consumption current of the semiconductor device in the present embodiment;

FIG. 6 is a view illustrating a configuration example of a first buffer circuit in the present embodiment;

FIG. 7 is a view illustrating another configuration example of the first buffer circuit in the present embodiment;

FIG. 8 is a view illustrating a configuration example of a circuit generating a bias voltage;

FIG. 9 is a circuit diagram illustrating a configuration example of the first buffer circuit and a second buffer circuit in the present embodiment;

FIG. 10 is a view illustrating a configuration example of a buffer circuit to which the present embodiment may be applied;

FIG. 11A is a view illustrating another example of a load in the buffer circuit to which the present embodiment may be applied;

FIG. 11B is a view illustrating another example of a load in the buffer circuit to which the present embodiment may be applied;

FIG. 12 is a view illustrating another configuration example of the buffer circuit to which the present embodiment may be applied;

FIG. 13 is a view illustrating another configuration example of the first buffer circuit in the present embodiment;

FIG. 14 is a view illustrating a configuration of a conventional CML type differential buffer circuit; and

FIG. 15 is a view illustrating an output waveform of the differential buffer circuit illustrated in FIG. 14.

### DESCRIPTION OF EMBODIMENTS

Hereinafter, embodiments are described based on the drawings.

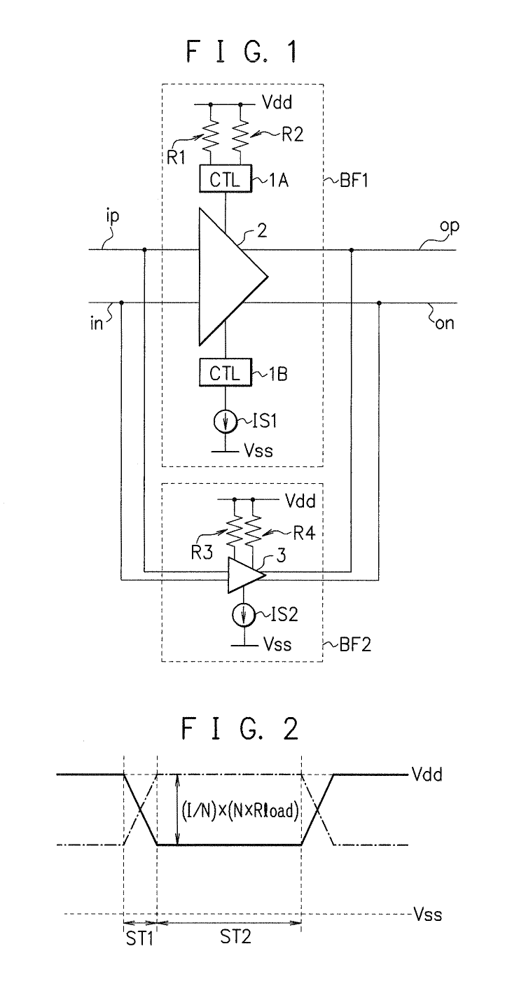

FIG. 1 is a view illustrating a configuration example of a semiconductor device according to a first embodiment. As illustrated in FIG. 1, the semiconductor device in the present embodiment transmits input signals (input data, input clocks, and so on) “ip”, “in” as output signals (output data, output clocks, and so on) “op”, “on”. The semiconductor device in the present embodiment has a first buffer circuit (differential buffer circuit) BF1 and a second buffer circuit (differential buffer circuit) BF2 coupled in parallel.

The first buffer circuit BF1 and the second buffer circuit BF2 are both CML type buffer circuits. The first buffer circuit BF1 has higher drive capability and may perform a high-speed operation compared to the second buffer circuit BF2. Besides, a current consumption (power consumption) of the second buffer circuit BF2 is small though the drive capability thereof is lower than the first buffer circuit. Incidentally, the first buffer circuit BF1 is used to change the output signals “op”, “on” in accordance with transitions of the input signals “ip”, “in”, and it is activated at a state transition time of the input signals “ip”, “in” (a period ST1 illustrated in FIG. 2), though the details are described later. Besides, the second buffer circuit BF2 is mainly used to maintain amplitudes of the output signals “op”, “on”, and it is activated at least during a period of an amplitude maintenance (a period ST2 illustrated in FIG. 2).

The first buffer circuit BF1 has resistances R1, R2 as loads, control circuits 1A, 1B, a drive circuit 2, and a current source IS1. One ends of the resistances R1, R2 are coupled to a power supply line to which a power supply voltage Vdd is supplied, and the other ends thereof are coupled to the drive circuit 2 via the control circuit 1A. One end of the current source IS1 is coupled relative to a reference potential Vss, and the other end is coupled to the drive circuit 2 via the control circuit 1B. The input signals “ip”, “in” are inputted to the drive circuit 2, and they are driven and outputted as the output signals “op”, “on”.

The control circuits 1A, 1B respectively detect transitions of the input signals “ip”, “in”, and control whether the first buffer circuit BF1 is to be activated or not in accordance with detected results.

For example, the control circuit 1B stops a current supply by the current source IS1, and the control circuit 1A detaches a coupling between the resistances R1, R2 as the loads and the drive circuit 2 and inactivates the first buffer circuit BF1, when the input signals “ip”, “in” do not make the transitions (a period when they do not make the transitions).

On the other hand, the control circuit 1A couples the resistances R1, R2 and the drive circuit 2 and the control circuit 1B controls to perform the current supply by the current source I51, when the transitions of the input signals “ip”, “in” are detected. The first buffer circuit BF1 is thereby activated, and voltages of the output signals “op”, “on” are changed into high-speed in accordance with the input signals “ip”, “in”. The control circuits 1A, 1B activate the first buffer circuit BF1, and inactivate the first buffer circuit BF1 again after the voltages of the output signals “op”, “on” reach predetermined voltages, or after a definite period of time has passed.

The second buffer circuit BF2 has resistances R3, R4 as loads, a drive circuit 3, and a current source IS2. One ends of the resistances R3, R4 are coupled to a power supply line to which the power supply voltage Vdd is supplied, and the other ends are coupled to the drive circuit 3. One end of the current source IS2 is coupled relative to the reference potential Vss, and the other end is coupled to the drive circuit 3. The input signals “ip”, “in” are inputted to the drive circuit 3, and they are driven and outputted as the output signals “op”, “on”.

The second buffer circuit BF2 does not have a control circuit such as the control circuits 1A, 1B held by the first buffer circuit BF1, and it is constantly activated. The second buffer circuit BF2 is mainly used to maintain amplitudes of the output signals “op”, “on” when the first buffer circuit BF1 is in an inactivation state.

Incidentally, the second buffer circuit BF2 is constantly activated in the present embodiment, but it is not limited to the above. For example, control circuits similar to the control circuits 1A, 1B are provided inside the second buffer circuit BF2, and the second buffer circuit BF2 may be inactivated when the first buffer circuit BF1 is in the activation state in accordance with the transitions of the input signals “ip”, “in”. Namely, the first buffer circuit BF1 and the second buffer circuit BF2 may be exclusively inactivated in accordance with the detection results of the transitions of the input signals “ip”, “in”.

Here, a size of the loads (resistance value) by the resistances R1, R2 as the loads held by the first buffer circuit BF1 is set as “Rload”, and a current value of the current source IS1 is set as “I”. Namely, an amplitude of the output signal is represented by (I×Rload).

In the present embodiment, a size of the loads (resistance value) by the resistances R3, R4 as the loads held by the second buffer circuit BF2 is set to be N times (N>1) of the size Rload of the loads by the resistances R1, R2 (N×Rload). Accordingly, a current value of the current source IS2 becomes (I/N) when the amplitude of the output signal (I×Rload) is maintained by the second buffer circuit BF2.

Accordingly, the first buffer circuit BF1 is activated to change the output signals “op”, “on” into high speed when the input signals “ip”, “in” make the transitions. The first buffer circuit BF1 is inactivated and the amplitudes of the output signals “op”, “on” are maintained by the second buffer circuit BF2 when the input signals “ip”, “in” do not make the transitions. Namely, it is possible to drive the semiconductor device with a small current during the amplitude maintenance period while making the large current flow during the period when transitions of the output signals are made, and to reduce the consumption current (power consumption) according to the maintenance of the amplitudes of the output signals up to (1/N). It is therefore possible to reduce the consumption current according to the amplitude maintenance of the output signals and to reduce the power consumption at a low-frequency operation time without damaging the high-speed operation performance as the buffer circuit in the semiconductor device.

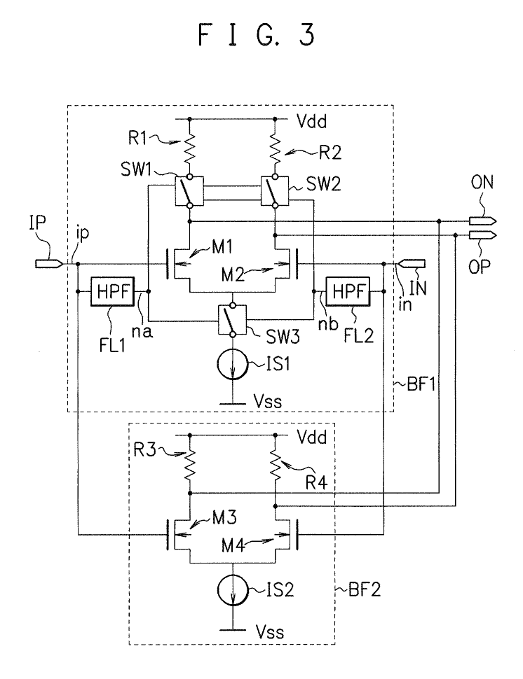

FIG. 3 is a circuit diagram illustrating a concrete configuration example of the semiconductor device in the present embodiment. In FIG. 3, the similar reference symbols are added to components having the similar functions as the components illustrated in FIG. 1.

The first buffer circuit BF1 has the resistances R1, R2 as the loads, N-channel type transistors M1, M2, the current source IS1, switching circuits SW1, SW2, SW3, and high-pass filters (HPF) FL1,

FL2. The first buffer circuit BF1 is constituted by having a differential pair constituted by the N-channel type transistors M1, M2.

One ends of the resistances R1, R2 are coupled to the power supply line to which the power supply voltage Vdd is supplied. The other end of the resistance R1 is coupled to a drain of the N-channel type transistor M1 via the switching circuit SW1, and the other end of the resistance R2 is coupled to a drain of the N-channel type transistor M2 via the switching circuit SW2. One end of the current source IS1 is coupled relative to the reference potential Vss, and the other end is coupled to sources of the N-channel type transistors M1, M2 via the switching circuit SW3.

The N-channel type transistors Ml, M2 are constituted by, for example, MOS transistors and so on. The input signal “ip” from the input terminal IP is inputted to a gate of the N-channel type transistor M1, and a coupling point between the drain of the N-channel type transistor M1 and the switching circuit SW1 is coupled to the output terminal ON. Besides, the input signal “in” from the input terminal IN is inputted to a gate of the N-channel type transistor M2, and a coupling point between the drain of the N-channel type transistor M2 and the switching circuit SW2 is coupled to the output terminal OP.

Besides, the input signal “ip” inputted from the input terminal IP is supplied to the switching circuits SW1, SW2, SW3 via the high-pass filter FL1 as a signal transition detecting circuit detecting the transition of the input signal “ip”. Similarly, the input signal “in” inputted from the input terminal IN is supplied to the switching circuits SW1, SW2, SW3 via the high-pass filter FL2 as the signal transition detecting circuit detecting the transition of the input signal “in”. Incidentally, the high-pass filter is used as the signal transition detecting circuit in the present embodiment, but it is not limited to the above, but an arbitrary circuit capable of detecting the transition of a signal may be applied, and for example, it may be a band-pass filter.

The switching circuits SW1, SW2, SW3 respectively have two control input terminals, and they become ON state (a state in which a switch is closed) when inputs to at least one of the control input terminals (outputs of the high-pass filters FL1, FL2) is in high level. Namely, the switching circuits SW1, SW2, SW3 are ON/OFF controlled in accordance with the outputs of the high-pass filters FL1, FL2 (detection results of the transitions of the input signals).

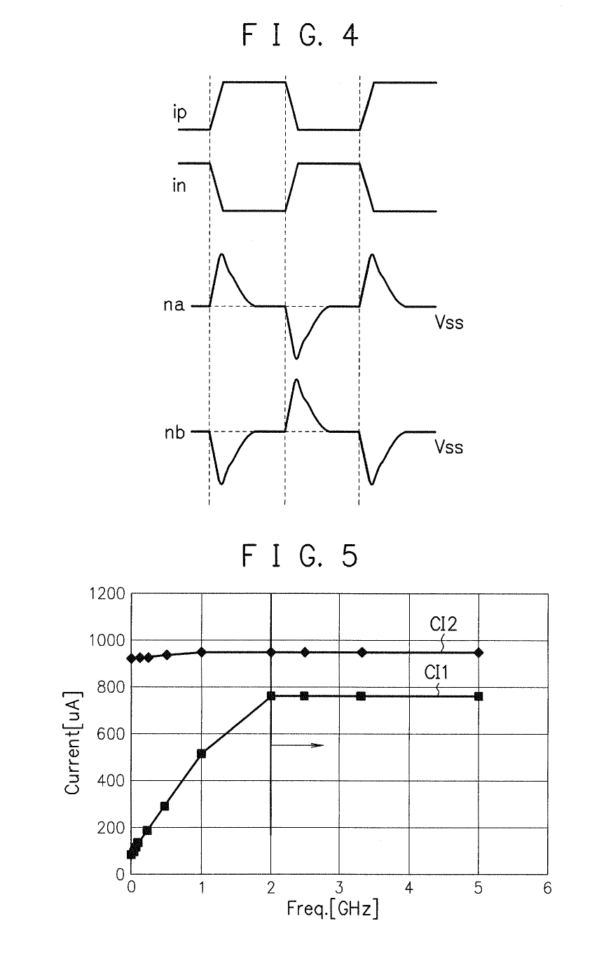

Here, the control circuit 1A illustrated in FIG. 1 is constituted by the high-pass filters FL1, FL2, and the switching circuits SW1, SW2. The control circuit 1B illustrated in FIG. 1 is constituted by the high-pass filters FL1, FL2 and the switching circuit SW3. For example, when the input signals “ip”, “in” illustrated in FIG. 4 are inputted from the input terminals IP, IN, output waveforms at respective output nodes of the high-pass filters FL1, FL2 are the ones represented by reference symbols “na”, “nb”. The switching circuits SW1, SW2, SW3 become ON states and the first buffer circuit BF1 is activated during a period when the input signals “ip”, “in” make state transitions, and when at least one of the output waveforms “na”, “nb” exceeds a predetermined voltage and is in high level. Incidentally, it is possible to control the period when the output waveforms “na”, “nb” become in high level by a time constant determined in accordance with resistances and capacitances (including parasitic capacitances of the transistors and so on) constituting the high-pass filters FL1, FL2.

Besides, the second buffer circuit BF2 has the resistances

R3, R4 as the loads, N-channel type transistors M3, M4, and the current source IS2. The second buffer circuit BF2 is constituted by having a differential pair constituted by the N-channel type transistors M3, M4.

One ends of the resistances R3, R4 are coupled to the power supply line to which the power supply voltage Vdd is supplied. The other end of the resistance R3 is coupled to a drain of the N-channel type transistor M3, and the other end of the resistance R4 is coupled to a drain of the N-channel type transistor M4. Incidentally, resistance values (loads) of the resistances R3, R4 are N times (N>1) of the resistance values (loads) of the resistances R1, R2. One end of the current source IS2 is coupled relative to the reference potential Vss, and the other end is coupled to sources of the N-channel type transistors M3, M4.

The N-channel type transistors M3, M4 are constituted by, for example, MOS transistors and so on. The input signal “ip” is inputted to a gate of the N-channel type transistor M3, and a coupling point between the drain of the N-channel type transistor M3 and the resistance R3 is coupled to the output terminal ON. Besides, the input signal “in” is inputted to a gate of the N-channel type transistor M4, and a coupling point between the drain of the N-channel type transistor M4 and the resistance R4 is coupled to the output terminal OP.

FIG. 5 is a view representing a relationship between an operating frequency and a consumption current of the semiconductor device in the present embodiment. In FIG. 5, a horizontal axis is the operating frequency, a vertical axis is the consumption current, and a reference symbol CI1 represents the consumption current in accordance with the operating frequency of the semiconductor device in the present embodiment. Incidentally, a consumption current in accordance with an operating frequency in a conventional differential buffer circuit is represented by a reference symbol CI2 for a comparative reference, in FIG. 5.

In an example illustrated in FIG. 5, the consumption current CI1 of the semiconductor device in the present embodiment changes linearly in accordance with the operating frequency at an operation time in low-frequency in which the operating frequency is 2 GHz or less. When the frequency approximates to a cut-off frequency of the high-pass filters FL1, FL2, the first buffer circuit BF1 and the second buffer circuit BF2 may be taken as the CML type buffer circuits coupled in parallel because the switching circuits SW1, SW2, SW3 are constantly in ON states, and a deterioration as a band is seldom seen.

According to the semiconductor device in the present embodiment, it is possible to change the power consumption in accordance with the frequency at the low-frequency operation time, and to reduce the power consumption in a frequency scaling without damaging the high-speed operation performance. It is thereby possible to solve problems such as a performance degradation, a shortening of an operating life, a shortening of a battery driving time of the semiconductor device caused by heat generation. Besides, a necessity to perform a countermeasure against heat release for the semiconductor device decreases, and a manufacturing cost may be reduced.

Hereinafter, concrete configuration examples and so on of the respective buffer circuits BF1, BF2 are described.

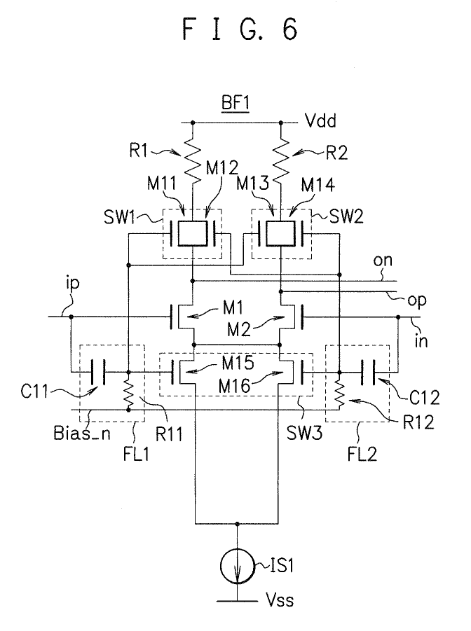

FIG. 6 is a circuit diagram illustrating a configuration example of the first buffer circuit BF1 in the present embodiment. In FIG. 6, the similar reference symbols are added to components having the similar functions as the components illustrated in FIG. 1 and FIG. 3, and redundant description is not given. Besides, overall operations and so on of the first buffer circuit BF1 illustrated in FIG. 6 are similar to the above-stated first buffer circuit BF1, and therefore, the description is not given.

In an example illustrated in FIG. 6, the switching circuit SW1 is constituted by N-channel type transistors M11, M12, the switching circuit SW2 is constituted by N-channel type transistors M13, M14, and the switching circuit SW3 is constituted by N-channel type transistors M15, M16. Besides, the high-pass filter FL1 is constituted by a capacitance C11 and a resistance R11, and the high-pass filter FL2 is constituted by a capacitance C12 and a resistance R12.

Sources and drains of the N-channel type transistors M11, M12 are respectively coupled to the resistance R1 and the drain of the N-channel type transistor M1. Sources and drains of the N-channel type transistors M13, M14 are respectively coupled to the resistance R2 and the drain of the N-channel type transistor M2. Sources and drains of the N-channel type transistors M15, M16 are respectively coupled to the current source IS1 and the sources of the N-channel type transistors M1, M2.

Besides, the input signal “ip” is supplied to a first electrode of the capacitance C11, and a second electrode thereof is coupled to one end of the resistance R11. The input signal “in” is supplied to a first electrode of the capacitance C12, and a second electrode thereof is coupled to one end of the resistance R12. The other ends of the resistances R11, R12 are coupled to a signal line to which a predetermined voltage Bias_n is supplied.

A coupling point between the second electrode of the capacitance C11 and the resistance R11 is coupled to gates of the N-channel type transistors M11, M13, M15. A coupling point between the second electrode of the capacitance C12 and the resistance R12 is coupled to gates of the N-channel type transistors M12, M14, M16.

Here, the predetermined voltage Bias_n is set to be a voltage slightly lower than a threshold voltage Vthn of the N-channel type transistors M11 to M16. Accordingly, the voltages relating to the gates of the N-channel type transistors M11 to M16 are the threshold voltage Vthn or less when the input signals “ip”, “in” do not make the transitions. Namely, the switching circuits SW1 to SW3 are in OFF states, the current does not flow, and the first buffer circuit BF1 is not activated (in an inactivation state).

On the other hand, the voltages relating to the gates of the N-channel type transistors M11 to M16 become the threshold voltage Vthn or more by the outputs of the high-pass filters FL1, FL2 when the input signals “ip”, “in” make the transitions. Accordingly, the switching circuits SW1 to SW3 are in ON states, and the first buffer circuit BF1 is activated.

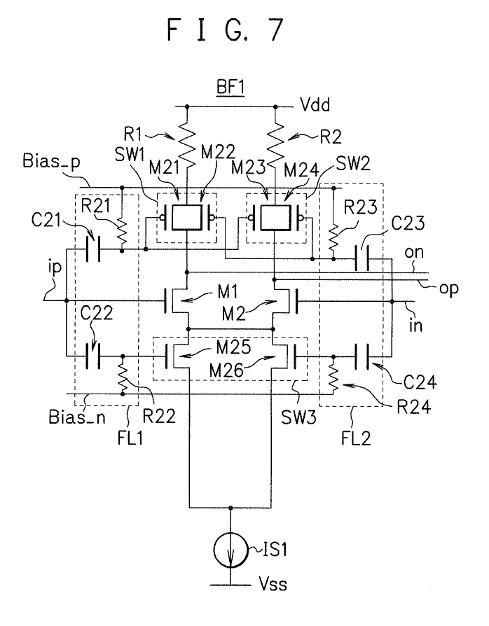

FIG. 7 is a circuit diagram illustrating another configuration example of the first buffer circuit BF1 in the present embodiment. In FIG. 7, the similar reference symbols are added to components having the similar functions as the components illustrated in FIG. 1 and FIG. 3, and redundant description is not given. Besides, overall operations and so on of the first buffer circuit BF1 illustrated in FIG. 7 are similar to the above-stated first buffer circuit BF1, and therefore, the description is not given.

In an example illustrated in FIG. 7, the switching circuit SW1 is constituted by P-channel type transistors M21, M22, the switching circuit SW2 is constituted by P-channel type transistors M23, M24, and the switching circuit SW3 is constituted by N-channel type transistors M25, M26. Besides, the high-pass filter FL1 is constituted by capacitances C21, C22 and resistances R21, R22, and the high-pass filter FL2 is constituted by capacitances C23, C24 and resistances R23, R24.

Sources and drains of the P-channel type transistors M21, M22 are respectively coupled to the resistance R1 and the drain of the N-channel type transistor M1. Sources and drains of the P-channel type transistors M23, M24 are respectively coupled to the resistance R2 and the drain of the N-channel type transistor M2. Sources and drains of the N-channel type transistors M25, M26 are respectively coupled to the current source IS1 and the sources of the N-channel type transistors M1, M2.

Besides, the input signal “ip” is supplied to first electrodes of the capacitances C21, C22. A second electrode of the capacitance C21 is coupled to one end of the resistance R21, and a second electrode of the capacitance C22 is coupled to one end of the resistance R22. Similarly, the input signal “in” is supplied to first electrodes of the capacitances C23, C24. A second electrode of the capacitance C23 is coupled to one end of the resistance R23, and a second electrode of the capacitance C24 is coupled to one end of the resistance R24.

The other ends of the resistances R21, R23 are coupled to a signal line to which a predetermined voltage Bias_p is supplied, and the other ends of the resistances R22, R24 are coupled to the signal line to which the predetermined voltage Bias_n is supplied.

A coupling point between the second electrode of the capacitance C21 and the resistance R21 is coupled to gates of the P-channel type transistors M21, M23. A coupling point between the second electrode of the capacitance C23 and the resistance R23 is coupled to gates of the P-channel type transistors M22, M24. Besides, a coupling point between the second electrode of the capacitance C22 and the resistance R22 is coupled to a gate of the N-channel type transistor M25, and a coupling point between the second electrode of the capacitance C24 and the resistance R24 is coupled to a gate of the N-channel type transistor M26.

Here, the predetermined voltage Bias_n is set at a voltage slightly lower than the threshold voltage Vthn of the N-channel type transistors M25, M26, and the predetermined voltage Bias_p is set at a voltage slightly higher than a threshold voltage Vthp of the P-channel type transistors M21 to M24.

By having the constitution as stated above, the switching circuits SW1 to SW3 are in OFF states, the current does not flow, and the first buffer circuit BF1 is not activated (in the inactivation state) when the input signals “ip”, “in” do not make the transitions as similar to the example illustrated in FIG. 6. On the other hand, the switching circuits SW1 to SW3 are in ON states, and the first buffer circuit BF1 is activated when the input signals “ip”, “in” make the transitions.

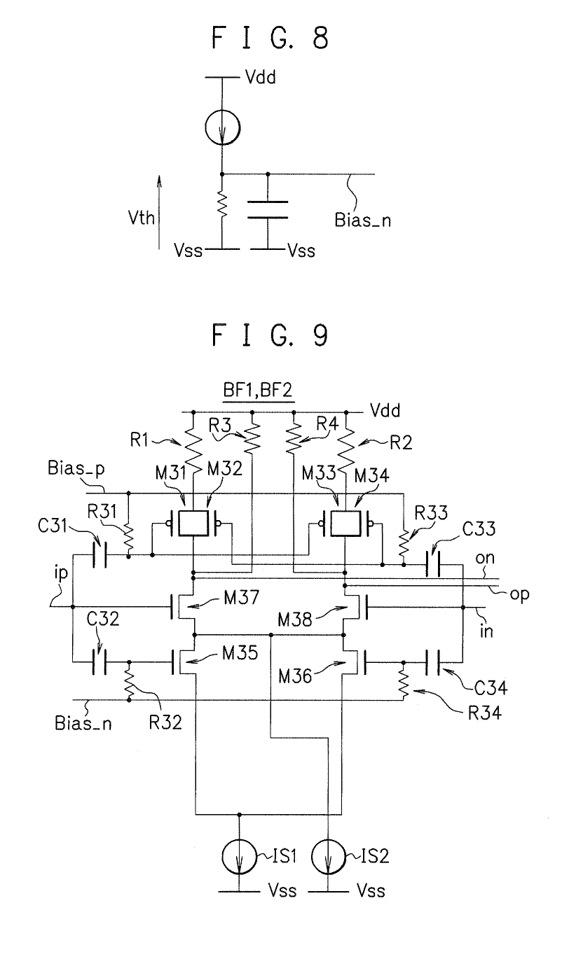

FIG. 8 is a view illustrating a configuration example of a circuit generating the predetermined voltage Bias_n illustrated in FIG. 6 and FIG. 7. The predetermined voltage Bias_n applied to the N-channel type transistors constituting the switching circuits is generated by a current source and a resistance coupled in series. Incidentally, the voltage Bias_n may be required to be stable because a malfunction of the switching circuit may occur if it is unstable, and therefore, the voltage Bias_n loads a capacitance. Incidentally, it is also possible to generate the predetermined voltage Bias_p illustrated in FIG. 7 by a circuit similar to the above.

FIG. 9 is a circuit diagram illustrating a configuration example of the first buffer circuit BF1 and the second buffer circuit BF2 in the present embodiment. In FIG. 9, the similar reference symbols are added to components having the similar functions as the components illustrated in FIG. 1, FIG. 3, FIG. 6 and FIG. 7, and redundant description is not given.

In an example illustrated in FIG. 9, the first buffer circuit BF1 and the second buffer circuit BF2 are constituted as one buffer circuit. In more detail, at least a part of circuit elements constituting the first buffer circuit BF1 and the second buffer circuit BF2 are commonly used by the first buffer circuit BF1 and the second buffer circuit BF2.

The switching circuit SW1 is constituted by P-channel type transistors M31, M32, the switching circuit SW2 is constituted by P-channel type transistors M33, M34, and the switching circuit SW3 is constituted by N-channel type transistors M35, M36. Besides, the high-pass filter FL1 is constituted by capacitances C31, C32 and resistances R31, R32, and the high-pass filter FL2 is constituted by capacitances C33, C34 and resistances R33, R34.

Incidentally, constitutions of the switching circuits SW1 to SW3, the high-pass filters FL1, FL2 are respectively the similar to the corresponding constitutions illustrated in FIG. 7, and the descriptions are not given.

An N-channel type transistor M37 illustrated in FIG. 9 corresponds to the above-stated N-channel type transistors M1 and M3. An N-channel type transistor M38 illustrated in FIG. 9 corresponds to the above-stated N-channel type transistors M2 and M4.

Namely, in an example illustrated in FIG. 9, the differential pairs inside the first and second buffer circuits BF1, BF2 are provided by a differential pair constituted by the commonly used N-channel type transistors M37, M38, and functions as the first and second buffer circuits BF1, BF2 are achieved by coupling the current sources IS1, IS2 and the resistances R1, R2, R3, R4 as the loads in parallel so as to correspond thereto.

Namely, the transistors M31 to M36 constituting the switching circuits SW1 to SW3 are in OFF states when the input signals “ip”, “in” do not make the transitions, and the function as the second buffer circuit BF2 is provided. Besides, the transistors M31 to M36 constituting the switching circuits SW1 to SW3 are in ON states when the input signals “ip”, “in” make the transitions, and the functions as the first and second buffer circuits BF1, BF2 are provided.

Incidentally, the buffer circuit using the resistance as the load is represented as an example in the above-stated description, but it is not limited to the above, but the present embodiment is applicable for a differential buffer circuit driven by the current source with an arbitrary load.

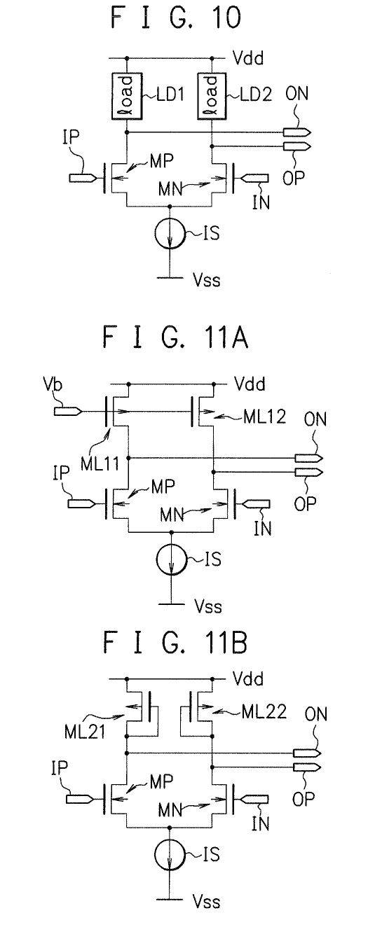

FIG. 10 is a view illustrating a configuration example of a buffer circuit to which the present embodiment may be applied.

In FIG. 10, reference symbols IP, IN are input terminals to which input signals are inputted, and they are respectively coupled to gates of N-channel type transistors MP, MN. Sources of the N-channel type transistors MP, MN are coupled to a current source IS of which one end is coupled relative to a reference potential Vss.

Besides, drains of the N-channel type transistors MP, MN are coupled to a power supply line to which a power source potential Vdd is supplied via arbitrary loads LD1, LD2. A coupling point between the drain of the N-channel type transistor MN and the load LD2 is coupled to an output terminal OP, and a coupling point between the drain of the N-channel type transistor MP and the load LD1 is coupled to an output terminal ON.

The art in the above-described embodiment is applicable for the buffer circuit illustrated in FIG. 10. Besides, an example constituting loads by P-channel type transistors ML11, ML12 is illustrated in FIG. 11A, and an example constituting loads by N-channel type transistors ML21, ML22 is illustrated in FIG. 11B.

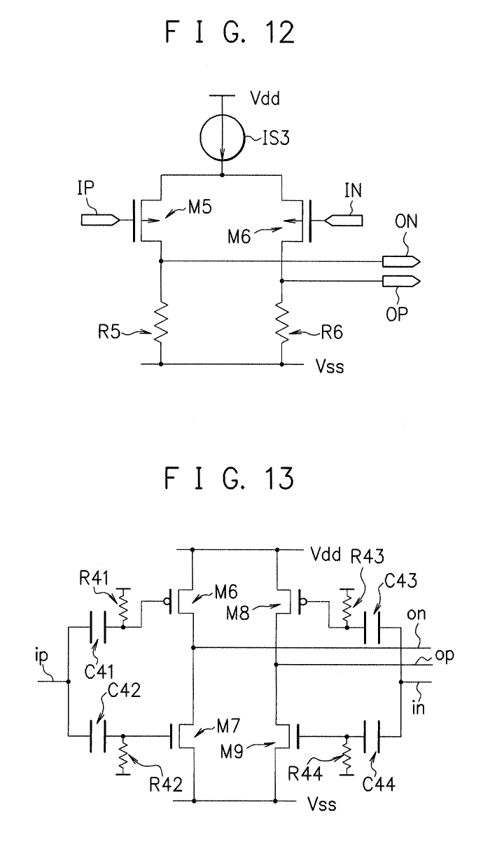

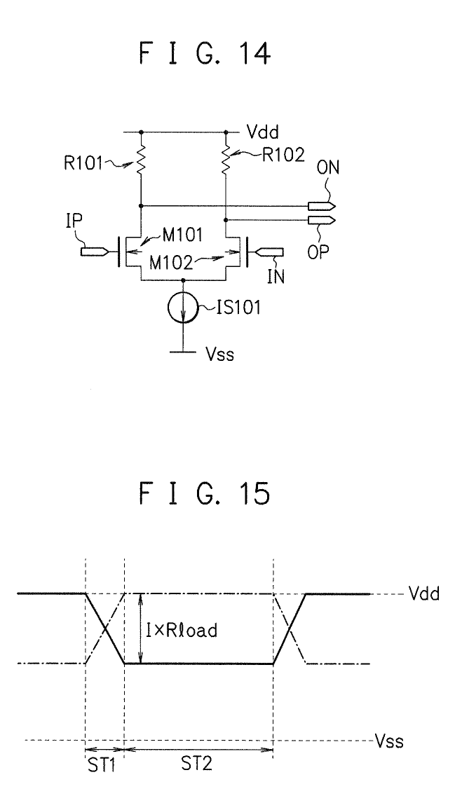

Besides, in the above description, a buffer circuit is described as an example in which the input signals are inputted to the N-channel type transistors constituting the differential pair, namely, the gates of the N-channel type transistors constituting the differential pair are coupled to the input terminals IP, IN, but the present embodiment is not limited to the above. It is applicable for a buffer circuit in which the input signals are inputted to the P-channel type transistors constituting the differential pair as illustrated in FIG. 12.

FIG. 12 is a view illustrating another configuration example of a buffer circuit to which the present embodiment is applicable. In FIG. 12, reference symbols IP, IN are input terminals to which input signals are inputted, and they are respectively coupled to gates of P-channel type transistors M5, M6. Sources of the P-channel type transistors M5, M6 are coupled to a current source IS3 in which a power supply voltage Vdd is supplied to one end thereof.

Besides, drains of the P-channel type transistors M5, M6 are coupled relative to a reference potential Vss via resistances R5, R6 as loads (it is an example, and the loads are arbitrary). A coupling point between the drain of the P-channel type transistor M6 and the resistance R6 is coupled to an output terminal OP, and a coupling point between the drain of the P-channel type transistor M5 and the resistance R5 is coupled to an output terminal ON.

Besides, in the above description, a case when both of the first and second buffer circuits BF1, BF2 are constituted by using differential pairs is represented as an example. However, the first buffer circuit BF1 is not necessary to be controlled by the current source and the load such as the resistance, because a large current is required when the output signal is changed. Accordingly, the first buffer circuit BF1 may be constituted by an inverter as illustrated in FIG. 13 though there is a possibility in which an undershoot or an overshoot may be generated because the amplitude control is not performed.

FIG. 13 is a view illustrating another configuration example of a first buffer circuit in the present embodiment. In FIG. 13, a P-channel type transistor M6 and an N-channel type transistor M7 are transistors constituting a first inverter. Similarly, a P-channel type transistor M8 and an N-channel type transistor M9 are transistors constituting a second inverter. A potential of an output node in the first inverter is outputted as an output signal “on”, and a potential of an output node in the second inverter is outputted as an output signal “op”.

An input signal “ip” is supplied to a gate of the P-channel type transistor M6 via a high-pass filter constituted by a capacitance C41 and a resistance R41, and the input signal “ip” is supplied to a gate of the N-channel type transistor M7 via a high-pass filter constituted by a capacitance C42 and a resistance R42. Similarly, an input signal “in” is supplied to a gate of the P-channel type transistor M8 via a high-pass filter constituted by a capacitance C43 and a resistance R43, and the input signal “in” is supplied to a gate of the N-channel type transistor M9 via a high-pass filter constituted by a capacitance C44 and a resistance R44.

According to the present embodiment, transitions of input signals are detected, and output signals may be changed by a first buffer circuit capable of performing a high-speed operation when the input signals make the transitions, and amplitudes of the output signals may be maintained by a second buffer circuit while making the first buffer circuit in an inactivation state when the amplitudes of the output signals are to be maintained. Accordingly, it is possible to reduce power consumption at a low-frequency operation time while maintaining a high-speed operation performance.

Numbers applying embodiments (first, second or third etc.) do not show priorities of the embodiments. Many variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments have been described in detail, it should be understood that the various changes, substitutions, and alterations could be made hereto without departing from the spirit and scope of the invention.

What is claimed is:

1. A semiconductor device comprising:
a first buffer circuit transmitting input signals;
a second buffer circuit having a lower drive capability than the first buffer circuit and transmitting the input signals; and
a control circuit detecting transitions of the input signals, and activating the first buffer circuit during a period when the input signals make the transitions.

2. The semiconductor device according to claim 1, wherein
the control circuit enables a current supply from a current source held by the first buffer circuit during the period when the input signals make the transitions.

3. The semiconductor device according to claim 1, wherein
a load held by the second buffer circuit is N times (N>1) of a load held by the first buffer circuit.

4. The semiconductor device according to claim 1, wherein
the control circuit activates the first buffer circuit when the transitions of the input signals are detected, and after the activation of the first buffer circuit, inactivates the first buffer circuit after an output signal reaches a definite voltage or after a definite period of time has passed.

5. The semiconductor device according to claim 1, wherein
the control circuit includes:
a signal transition detecting circuit detecting the transitions of the input signals; and
switching circuits being turned ON/OFF in accordance with a detection result by the signal transition detecting circuit and controlling a current supply to the first buffer circuit.

6. The semiconductor device according to claim 5, wherein
the signal transition detecting circuit is a high-pass filter or a band-pass filter.

7. The semiconductor device according to claim 1, wherein
the first buffer circuit and the second buffer circuit are coupled in parallel relative to the input signals.

8. The semiconductor device according to claim 1, wherein
the first buffer circuit and the second buffer circuit are constituted by one buffer circuit.

9. The semiconductor device according to claim 1, wherein
the first buffer circuit and the second buffer circuit commonly use at least a part of circuit elements constituting each buffer circuit.

10. The semiconductor device according to claim 1, wherein
the first buffer circuit is a circuit changing output signals in accordance with the transitions of the input signals, and
the second buffer circuit is a circuit maintaining amplitudes of the output signals.

11. The semiconductor device according to claim 1, wherein
the control circuit inactivates the second buffer circuit during a period when the input signals make the transitions.

12. The semiconductor device according to claim 1, wherein
the control circuit exclusively inactivates the first buffer circuit and the second buffer circuit in accordance with the detection result of the transitions of the input signals.

13. The semiconductor device according to claim 1, wherein
the first and second buffer circuits are constituted by using a differential pair.

14. The semiconductor device according to claim 1, wherein
the first buffer circuit is constituted by using an inverter, and the second buffer circuit is constituted by using a differential pair.

15. A semiconductor device, comprising:
a first and second buffer circuits coupled in parallel relative to input signals and transmitting the input signals, wherein
the first buffer circuit includes:
a first drive circuit to which the input signals are inputted;
a first load coupled to the first drive circuit via a first switching circuit; and
a first current source coupled to the first drive circuit via a second switching circuit, and
the second buffer circuit includes:
a second drive circuit of which drive capability is lower than the first drive circuit and to which the input signals are inputted;
a second load which is N times (N>1) of the first load, and coupled to the second drive circuit; and
a second current source coupled to the second drive circuit, and wherein
the first and second switching circuits are ON/OFF controlled in accordance with a detection result of the transitions of the input signals.
